(19) United States
(12) Patent Application Publication
(10) Pub. No.: US 2012/0027954 A1
(43) Pub. Date: Feb. 2, 2012

(54) MAGNET FOR PHYSICAL VAPOR DEPOSITION PROCESSES TO PRODUCE THIN FILMS HAVING LOW RESISTIVITY AND NON-UNIFORMITY

(75) Inventors: ZHENDONG LIU, San Jose, CA (US); YONG CAO, San Jose, CA (US); XIANMIN TANG, San Jose, CA (US); SRINIVAS GANDIKOTA, Santa Clara, CA (US); THANH NGUYEN, San Jose, CA (US); MUHAMMAD RASHEED, San Jose, CA (US)

(73) Assignee: APPLIED MATERIALS, INC., Santa Clara, CA (US)

(21) Appl. No.: 13/189,992

(22) Filed: Jul. 25, 2011

Related U.S. Application Data
(60) Provisional application No. 61/369,347, filed on Jul. 30, 2010.

(51) Int. Cl. C23C 14/35

(52) U.S. Cl. 427/571; 118/722

(57) ABSTRACT

Methods and apparatus for depositing thin films having high thickness uniformity and low resistivity are provided herein. In some embodiments, a magnetron assembly includes a shunt plate, the shunt plate rotatable about an axis, an inner closed loop magnetic pole coupled to the shunt plate, and an outer closed loop magnetic pole coupled the shunt plate, wherein an unbalance ratio of a magnetic field strength of the outer closed loop magnetic pole to a magnetic field strength of the inner closed loop magnetic pole is less than about 1. In some embodiments, the ratio is about 0.57. In some embodiments, the shunt plate and the outer close loop magnetic pole have a cardioid shape. A method utilizing RF and DC power in combination with the inventive magnetron assembly is also disclosed.

### CROSS-REFERENCE TO RELATED APPLICATIONS

This application claims benefit of U.S. provisional patent application Ser. No. 61/369,347, filed Jul. 30, 2010, which is herein incorporated by reference

### FIELD

Embodiments of the present invention generally relate to substrate processing, and more specifically to physical vapor deposition processes.

### BACKGROUND

In conventional physical vapor deposition (PVD) processes, for example for tungsten (W) deposition, only direct current (DC) power was applied for film deposition. While good thickness uniformity could be achieved with conventional magnetron designs, the resistivity of the resultant deposited W films was very high, which limits the density of transistor integration due to high line resistance. One technique to try to improve the properties of W films is radio frequency (RF)-assisted PVD deposition, in which the resistivity of the W film can be reduced significantly due to high-energy ion re-sputtering and film densification. However, due to RF power coupling of the plasma during the deposition process, the thickness uniformity of these W films is poor.

Thus, the inventors have provided apparatus and methods for PVD deposition of thin films having reduced resistivity and non-uniformity.

### SUMMARY

Methods and apparatus for depositing thin films having high thickness uniformity and low resistivity are provided herein. In some embodiments, a magnetron assembly includes a shunt plate, the shunt plate rotatable about an axis, an inner closed loop magnetic pole coupled to the shunt plate, and an outer closed loop magnetic pole coupled the shunt plate, wherein an unbalance ratio of a magnetic field strength of the outer closed loop magnetic pole to a magnetic field strength of the inner closed loop magnetic pole is less than about 1. In some embodiments, the ratio is about 0.57. In some embodiments, the outer closed loop magnetic pole has a cardioid shape.

In some embodiments, a method of processing a substrate in a physical vapor deposition (PVD) chamber includes providing a process gas having at least some ionic species into the PVD chamber, applying a DC power to a target disposed above a substrate to direct the ionic species towards the target, rotating a magnetron above the target, the magnetron having an inner closed loop magnetic pole and an outer closed loop magnetic pole, wherein an unbalance ratio of a magnetic field strength of the outer closed loop magnetic pole to a magnetic field strength of the inner closed loop magnetic pole is less than about 1, sputtering metal atoms from the target using the ionic species, depositing a first plurality of metal atoms on the substrate, applying an RF power to an electrode disposed beneath the substrate to re-sputter at least a portion of the deposited metal atoms using the ionic species, forming a layer on the substrate by applying the DC power and the RF power for a desired time period. In some embodiments, the layer comprises tungsten (W) and has a thickness uniformity of less than about 2% and a resistivity of less than about 10 μOhm-cm.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a bottom perspective view of a magnetron in accordance with some embodiments of the present invention.

FIG. 1A depicts a partial bottom view of a magnetron in accordance with some embodiments of the present invention.

FIG. 2 depicts side schematic view of a physical vapor deposition chamber in accordance with some embodiments of the present invention.

FIG. 3 depicts a graph of deposited layer thickness along a wafer surface as a function of unbalance ratio of an outer pole to an inner pole of a magnetron using DC power only in accordance with some embodiments of the present invention.

FIG. 4 depicts a graph of deposited layer thickness along a wafer surface as a function of unbalance ratio of an outer pole to inner pole of a magnetron using both RF and DC power in accordance with some embodiments of the present invention.

FIG. 5 depicts a graph of thickness uniformity and resistivity of a deposited layer as a function of unbalance ratio of an outer pole to inner pole of a magnetron in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods and apparatus for depositing thin films having high thickness uniformity and low resistivity are provided herein. Some embodiments of the inventive apparatus relate to magnetron designs for use in radio frequency (RF) physical vapor deposition (PVD) processes. Some embodiments of the method relate to depositing a thin film having high thickness uniformity (e.g., less than about 2%) and low resistivity (e.g., less than about 10 μOhm-cm).

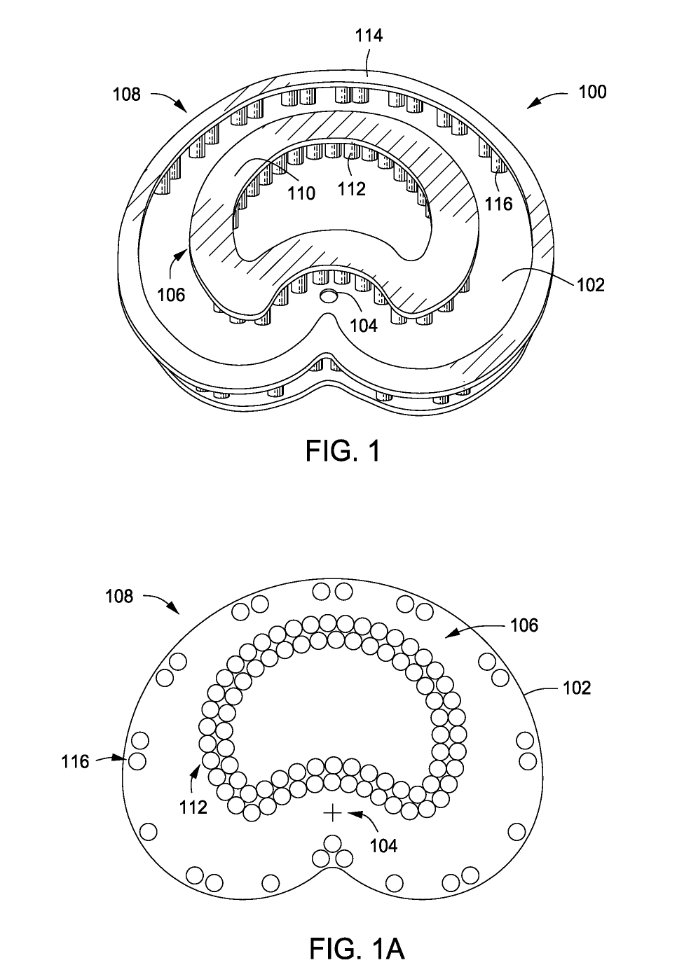

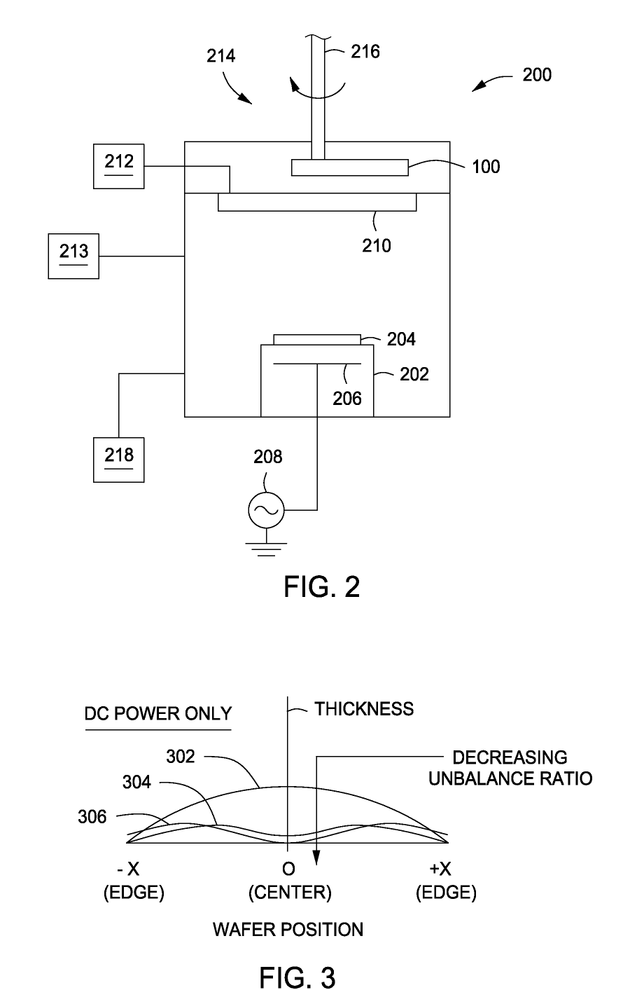

FIG. 1 depicts a magnetron in accordance with some embodiments of the present invention. The magnetrons of the present invention may generally be used in PVD chambers having DC power applied to a target and RF power applied to one or more of a substrate support or a target of the PVD chamber, for example such a PVD chamber 200 described below and depicted in FIG. 2. Non-limiting examples of processes that may benefit from utilization of the present inventive magnetron include tungsten (W) deposition processes, amongst other deposition processes.

FIG. 1 depicts a bottom perspective view of a magnetron 100 in accordance with some embodiments of the present invention. The magnetron 100 includes a shunt plate 102 which also serves as a structural base for the magnetron assembly. The shunt plate 102 may include an axis of rotation 104 about which the shunt plate 102 may rotate when coupled to a shaft. For example, a mounting plate (not shown) may be coupled to the shunt plate 102 to mount the shunt plate 102 to a shaft (e.g., shaft 216 illustrated in FIG. 2) to provide rotation of the magnetron 100 during use. In some embodiments, and as illustrated, the shunt plate 102 may have a cardioid shape. However, the shunt plate 102 may have other shapes as well.

The magnetron 100 includes at least two magnetic poles, for example, an inner pole 106 and an outer pole 108. Each of the inner and outer poles 106, 108 may form a closed loop magnetic field. As used herein, a closed loop magnetic field refers to a pole having no discrete beginning and end, but instead forms a loop. The polarity within a given pole is the same (e.g., north or south), but the polarity between each pole 106, 108 is opposite each other (e.g., inner north and outer south or inner south and outer north).

Each pole may include a plurality of magnets arranged between a pole plate and the shunt plate 102. For example, the inner pole 106 includes a pole plate 110 having a first plurality of magnets 112 disposed between the pole plate 110 and the shunt plate 102. Similarly, the outer pole 108 includes a pole plate 114 having a second plurality of magnets 116 disposed between the pole plate 114 and the shunt plate 102. The pole plates 110, 114 may be fabricated from a ferromagnetic material, such as in a non-limiting example, 400-series stainless steel or other suitable materials. The pole plates 110, 114 may have any suitable closed loop shape. The shapes of the pole plates 110, 114 may be similar such that a distance between the pole plates 110, 114 is generally uniform about the loop of the pole plates 110, 114. As illustrated, in some embodiments, the pole plate 114 may be in the shape of a cardioid. In some embodiments, the pole plate 114 may approximately trace a peripheral edge of the shunt plate 102.

The magnets in each plurality need not be completely uniformly distributed. For example, as illustrated in FIG. 1, in some embodiments, at least some magnets in the second plurality of magnets 116 may be arranged in pairs. As shown in FIG. 1A, the plurality of magnets may be disposed in multiple rows. For example, the first plurality of magnets 112 are shown disposed in two rows of magnets.

Returning to FIG. 1, in some embodiments, the magnetic strength of each magnet in the first and second pluralities 112, 116 may be equal. Alternatively, the magnetic strength of one or more magnets in the first and second pluralities 112, 116 may be different. In some embodiments, the strength of the magnetic field formed by the inner pole 106 may be stronger than the strength of the magnetic field formed by the outer pole 108. As such, in some embodiments, the magnets of the first plurality of magnets 112 may be more densely packed than the magnets of the second plurality 116. Alternatively or in combination, in some embodiments, the number of magnets in the first plurality 112 may exceed the number of magnets in the second plurality 116.

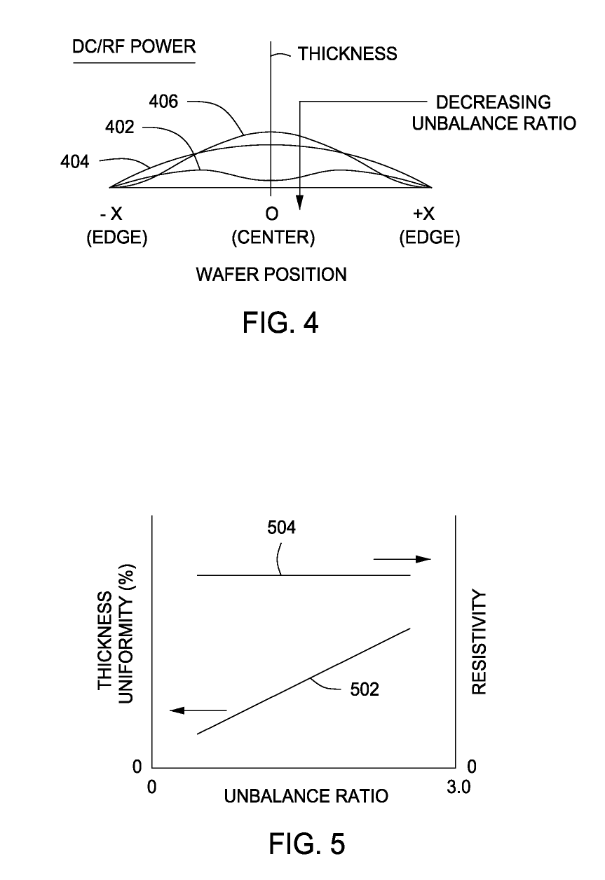

The disparity in the strength of the magnetic fields between the inner and outer poles 106, 108 may be defined by an unbalance ratio of a magnetic strength of the inner pole 106 to that of the outer pole 108. For example, in embodiments where each of the magnets in the first and second pluralities 112, 116 are equivalent magnets have equivalent magnetic field strength, the unbalance ratio may simply reduce to the ratio of a number of magnets in the second plurality 116 to a number of magnets in the first plurality 112. In the inventive magnetron disclosed herein, the inventors have discovered that having an unbalance ratio of less than about 1, e.g., less magnetic field strength in the outer pole 108 versus that of the inner pole 106 and/or less number of magnets in the second plurality 116 versus that of the first plurality 112, may be used to deposit a layer having high thickness uniformity and low resistivity as discussed above. For example, in some embodiments, a desirable unbalance ratio may be about 0.57. It is contemplated that other unbalance ratios may be used for certain applications. For example, as discussed below with respect to FIGS. 3-4, the inventors have discovered that the unbalance ratio may be selected or modified to control a thickness profile of a deposited film.

FIG. 2 depicts a side schematic view of a process chamber 200 in accordance with some embodiments of the invention. The process chamber 200 may be any suitable PVD chamber configured for DC, and optionally RF, power. In some embodiments, the process chamber 200 may be configured for both DC and RF power application, as discussed below. For example, the process chamber 200 includes a substrate support 202 having a substrate 204 disposed thereon. An electrode 206 may be disposed in the substrate support 204 for providing RF power to the process chamber 200. The RF power may be supplied to the electrode via an RF power supply 208. The RF power supply 208 may be coupled to the electrode 206 via a match network (not shown). Alternatively or in combination, (not shown) the RF power supply 208 (or another RF power supply) may be coupled to a target 210 disposed above the substrate support 202 (or to an electrode disposed proximate a backside of the target), for example, in a ceiling of the process chamber 200.

The target 210 may comprise any suitable metal and/or metal alloy for use in depositing a layer on the substrate 204. For example, in some embodiments, the target may comprise tungsten (W). A DC power supply 212 may be coupled to the target 210 to provide a bias voltage on the target 210 to direct a plasma formed in the chamber 200 towards the target 210. The plasma may be formed from a process gas, such as argon (Ar) or the like, provided to the chamber 200 by a gas source 213. A magnetron assembly 214 including the magnetron 100 and a shaft 216 for rotating the magnetron 100 is disposed above the target 210. The magnetron assembly 214 may, for example, facilitate uniform sputtering of metal atoms from the target 210, and/or uniform deposition of a layer of metal atoms on the substrate 204 having high thickness uniformity and low resistivity as discussed above.

A controller 218 may be provided and coupled to various components of the process chamber 200 to control the operation thereof. The controller 218 includes a central processing unit (CPU), a memory, and support circuits. The controller 218 may control the process chamber 200 directly, or via computers (or controllers) associated with particular process chamber and/or support system components. The controller 218 may be one of any form of general-purpose computer processor that can be used in an industrial setting for controlling various chambers and sub-processors. The memory, or computer readable medium, of the controller 218 may be one or more of readily available memory such as random access memory (RAM), read only memory (ROM), floppy disk, hard disk, optical storage media (e.g., compact disc or digital video disc), flash drive, or any other form of digital storage, local or remote. The support circuits are coupled to the CPU for supporting the processor in a conventional manner. These circuits include cache, power supplies, clock circuits, input/output circuitry and subsystems, and the like. Inventive methods as described herein may be stored in the memory as software routine that may be executed or invoked to control the operation of the process chamber 200 in the manner described herein. The software routine may also be stored and/or executed by a second CPU (not shown) that is remotely located from the hardware being controlled by the CPU.

In operation, a gas, such as argon (Ar) or the like is provided to the process chamber 200 from the gas source 213. The gas may be provided at a sufficient pressure, such that at least a portion of the gas includes ionized species, such as Ar ions. The ionized species are directed to the target 210 by a DC voltage applied to the target 210 by the DC power supply 212. The ionized species collide with the target 210 to eject metal atoms from the target 210. The metal atoms, for example, having a neutral charge fall towards the substrate 204 and deposit on the substrate surface. Concurrently, with the collision of the ionic species with the target 210 and the subsequent ejection of metal atoms, the magnetron 100 is rotated above the target 210 about the shaft 216. The magnetron 100 produces a magnetic field within the chamber 200, generally parallel and close to the surface of the target 210 to trap electrons which can collide with and ionize of any gas molecules proximate the target 210, which in turn increases the local ion species density proximate the surface of the target 210 and increases the sputtering rate. Further, RF power may be applied to the substrate support 202 by the RF power supply 208 during the sputtering of the metal atoms from the target 210. The RF power may be utilized to direct a portion of ionized species towards the deposited metal atoms on the substrate 204 to promote at least some re-sputtering of the deposited metal atoms from the layer being formed on the substrate 204. The re-sputtering of deposited metal atoms may reduce resistivity in the deposited layer and promote densification of the layer. However, as discussed below, the inventors have discovered that RF power alone may result in a layer having adequate resistivity but a center high-edge low profile. Accordingly, the inventive magnetron 100 having the desired unbalance ratio as discussed above may be utilized alone or in combination with the RF power to provide a desired deposition profile, for example, having a high thickness uniformity and a low resistivity.

FIG. 3 depicts a graph of deposited layer thickness along a wafer surface as a function of the unbalance ratio of the outer pole to the inner pole of a magnetron using DC power only in accordance with some embodiments of the invention. For example, when the unbalance ratio is substantially greater than about 1, such as about 2.7, the deposition profile has a center high-edge low profile as shown by plot 302. A magnetron having an unbalance ratio of greater than about 1 may be utilized to control the ion bombardment on the substrate and/or increase metal ionization by shrinking confinement volumes. For example, an unbalance ratio of less than about 1 can be used to modulate the deposition profile. For example, as shown in FIG. 3, a deposition profile having an unbalance ratio of less than 1 can have a center low-edge high profile, as shown by plots 304 (e.g., having an unbalance ratio of about 0.97) and 306 (e.g., having an unbalance ratio of about 0.57). In some embodiments, the lower the unbalance ratio, the lower the center deposition and higher the edge deposition (as shown by plots 304 and 306. However, with the addition of RF power (RF power alone would result in a center high-edge low profile as discussed above) a desired deposition profile may be achieved as shown below in FIG. 4.

FIG. 4 depicts a graph of deposited layer thickness along a wafer surface as a function of unbalance ratio of an outer pole to inner pole of a magnetron using both DC and RF power in accordance with some embodiments of the present invention. For example, as discussed above, the combination of RF and DC power using an unbalance ratio of less than 1 can be used to deposit a layer having high thickness uniformity and low resistivity. Since RF power was coupled through ESC at wafer center, a film deposition contributed from RF power has a thick center and thin edge profile. With the low unbalance ratio of the inventive magnetron 100, a deposition profile with thick wafer edge and thin wafer center can be realized with DC power PVD deposition, due to weak magnetic field bounding and plasma diffusion to wafer edge. Combining RF power and DC power deposition, uniform thickness profile can be achieved across the substrate. For example, as shown in FIG. 4 using DC and RF power to deposit a thin film, a large unbalance ratio (for example ranging from about 1 to about 2.72) can result in the deposition of a layer with a center high, edge low profile, as shown by plot 406. However, in embodiments where the unbalance ratio is low, for example, ranging from about 0.57 (e.g., plot 402) to about 0.93 (e.g., plot 404), such a process can result in the deposition of a layer having a more uniform profile, as illustrated in FIG. 4.

Further, as discussed above, RF power can improve resistivity in the deposited layer, but unfortunately when provided alone results in a center high-edge low profile of the deposited layer. Thus, by combining the RF power with the DC power using the inventive magnetron 100, a deposited layer having a high thickness uniformity and low resistivity can be achieved. As illustrated in FIG. 5, with the magnetron 100, the resistivity of the deposited layer may be much lower than the resistivity of a deposited layer using a conventional PVD process. FIG. 5 also indicates that changing the unbalance ratio in the magnetron 100 has little to no substantial effect on resistivity in the deposited layer, as shown by plot 504. However, as shown in FIG. 5 decreasing the unbalance ratio can substantially improve the thickness uniformity in the deposited layer, as shown by plot 502.

For example, in some embodiments, using the inventive methods and apparatus disclosed herein, the resistivity of a 500 angstrom tungsten (W) film was about 9.4 μOhm-cm, and the thickness uniformity was about 1.5%,. These results represent a significant improvement from a tungsten (W) film deposited using a conventional magnetron with DC power, which had resistivity of about 11 μOhm-cm or more, and thickness uniformity of 2.5%.

Thus, methods and apparatus for depositing thin films having high thickness uniformity and low resistivity have been provided herein. Some embodiments of the inventive apparatus relate to magnetron designs for use in radio frequency (RF) physical vapor deposition (PVD) processes. Some embodiments of the method relate to using RF and DC power, to deposit a thin film having high thickness uniformity (less than about 2%) and low resistivity (less than about 10 μOhm-cm).

While the foregoing is directed to embodiments of the present invention, other and further embodiments of the invention may be devised without departing from the basic scope thereof.

1. A magnetron assembly, comprising:
a shunt plate, the shunt plate rotatable about an axis;
an inner closed loop magnetic pole coupled to the shunt plate; and
an outer closed loop magnetic pole coupled the shunt plate, wherein an unbalance ratio of a magnetic field strength of the outer closed loop magnetic pole to a magnetic field strength of the inner closed loop magnetic pole is less than about 1.

2. The magnetron assembly of claim 1, wherein the unbalance ratio is about 0.57 to about 0.97.

3. The magnetron assembly of claim 1, wherein the unbalance ratio is about 0.57.

4. The magnetron assembly of claim 1, wherein a first polarity of the inner closed loop magnetic pole opposes a second polarity of the outer closed loop magnetic pole.

5. The magnetron assembly of claim 1, wherein the outer closed loop magnetic pole has a cardioid shape.

6. The magnetron assembly of claim 1, wherein the inner closed loop magnetic pole further comprises:
an inner pole plate; and
a plurality of first magnets disposed between the inner pole plate and the shunt plate.

7. The magnetron assembly of claim 6, wherein the outer closed loop magnetic pole further comprises:
an outer pole plate; and
a plurality of second magnets disposed between the outer pole plate and the shunt plate.

8. The magnetron assembly of claim 1, wherein the inner closed loop magnetic pole further comprises an inner pole plate and a plurality of first magnets disposed between the inner pole plate and the shunt plate, and wherein the outer closed loop magnetic pole further comprises an outer pole plate and a plurality of second magnets disposed between the outer pole plate and the shunt plate.

9. The magnetron assembly of claim 8, wherein each magnet in the first and second pluralities has equivalent magnetic strength.

10. The magnetron assembly of claim 8, wherein at least some magnets in the first and second pluralities have different magnetic strengths.

11. The magnetron assembly of claim 8, wherein a number of magnets in the first plurality is greater than a number of magnets in the second plurality.

12. A method of processing a substrate in a physical vapor deposition (PVD) chamber, the method comprising:
providing a process gas having at least some ionic species into the PVD chamber;
applying a DC power to a target disposed above a substrate to direct the ionic species towards the target;
rotating a magnetron above the target, the magnetron having an inner closed loop magnetic pole and an outer closed loop magnetic pole, wherein an unbalance ratio of a magnetic field strength of the outer closed loop magnetic pole to a magnetic field strength of the inner closed loop magnetic pole is less than about 1;
sputtering metal atoms from the target using the ionic species;
depositing a first plurality of metal atoms on the substrate;
applying an RF power to re-sputter at least a portion of the deposited metal atoms using the ionic species; and
forming a layer on the substrate by applying the DC power and the RF power for a desired time period.

13. The method of claim 12, wherein applying the RF power further comprises:
applying the RF power to an electrode disposed beneath the substrate.

14. The method of claim 12, wherein applying the RF power further comprises:
applying the RF power to the target or to an electrode disposed proximate the target.

15. The method of claim 12, wherein the target comprises tungsten (W).

16. The method of claim 12, wherein the layer comprises tungsten (W).

17. The method of claim 12, wherein the layer has a thickness uniformity of less than about 2 percent.

18. The method of claim 12, wherein the layer has a resistivity of less than about 10 μOhm-cm.

19. The method of claim 12, wherein the unbalance ratio is about 0.57 to about 0.97.
